(19) United States
(12) Patent Application Publication
(10) Pub. No.: US 2010/0050895 A1
(43) Pub. Date: Mar. 4, 2010

(54) PROCESSLESS LITHOGRAPHIC PRINTING PLATE

(75) Inventor: Hieronymus Andriessen, Beerse (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: Agfa Graphics NV, Mortsel (BE)

(21) Appl. No.: 12/439,804

(22) PCT Filed: Sep. 6, 2007
(86) PCT No.: PCT/EP2007/059348

§ 371 Date: Mar. 3, 2009

Related U.S. Application Data
(60) Provisional application No. 60/825,445, filed on Sep. 13, 2006.

(30) Foreign Application Priority Data
Sep. 12, 2006 (EP) 06120494.7

(51) Int. Cl. B41N 3/00; B41F 1/18; G03F 7/004

(52) U.S. Cl. 101/467; 101/450.1; 430/270.1

(57) ABSTRACT

According to the present invention a non-ablative, negative-working, heat-sensitive printing plate precursor is disclosed capable of switching from a hydrophilic state into a hydrophobic state upon exposure to heat and/or infrared light. The printing plate precursor is obtainable by the method comprising the step of providing on a support a titanium oxide layer by reactive physical vacuum deposition of titanium, characterised in that said vacuum deposition is carried out under a partial oxygen pressure of 10% or more and less than 25%.

### FIELD OF THE INVENTION

The present invention relates to a non-ablative, negative-working, heat-sensitive printing plate precursor.

### BACKGROUND OF THE INVENTION

Lithographic printing presses use a so-called printing master such as a printing plate which is mounted on a cylinder of the printing press. The master carries a lithographic image on its surface and a print is obtained by applying ink to said image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. In so-called driographic printing, the lithographic image consists of ink-accepting and ink-adhesive (ink-repelling) areas and during driographic printing, only ink is supplied to the master.

Printing masters are generally obtained by the image-wise exposure and processing of an imaging material called plate precursor. In addition to the well-known photosensitive, so-called pre-sensitized plates, which are suitable for UV contact exposure through a film mask, also heat-sensitive printing plate precursors have become very popular in the late 1990s. Such thermal materials offer the advantage of daylight stability and are especially used in the so-called computer-to-plate method wherein the plate precursor is directly exposed, i.e. without the use of a film mask. The material is exposed to heat or to infrared light and the generated heat triggers a (physico-)chemical process, such as ablation, polymerization, insolubilization by cross linking of a polymer, heat-induced solubilization, or by particle coagulation of a thermoplastic polymer latex.

The most popular thermal plates form an image by a heat-induced solubility difference in an alkaline developer between exposed and non-exposed areas of the coating. The coating typically comprises an oleophilic binder, e.g. a phenolic resin, of which the rate of dissolution in the developer is either reduced (negative working) or increased (positive working) by the image-wise exposure. During processing, the solubility differential leads to the removal of the non-image (non-printing) areas of the coating, thereby revealing the hydrophilic support, while the image (printing) areas of the coating remain on the support. Typical examples of such plates are described in e.g. EP-A 625728, 823327, 825927, 864420, 894622 and 901902. Negative working embodiments of such thermal materials often require a pre-heat step between exposure and development as described in e.g. EP-A 625,728.

Some of these thermal processes enable plate making without wet processing and are for example based on ablation of one or more layers of the coating. At the exposed areas the surface of an underlying layer is revealed which has a different affinity towards ink or fountain than the surface of the unexposed coating.

Most ablative plates generate ablation debris which may contaminate the electronics and optics of the exposure device and which needs to be removed from the plate by wiping it with a cleaning solvent, so that ablative plates are often not truly processless. Ablation debris which is deposited onto the plate's surface may also interfere during the printing process and result in for example scumming.

Other thermal processes which enable plate making without wet processing are for example processes based on a heat-induced hydrophilic/oleophilic conversion of one or more layers of the coating so that at exposed areas a different affinity towards ink or fountain is created than at the surface of the unexposed coating.

U.S. Pat. No. 5,855,173, U.S. Pat. Nos. 5,839,369 and 5,839,370 describe a method relying on the image-wise hydrophilic-hydrophobic transition of a ceramic such as a zirconia ceramic and the subsequent reverse transition in an image erasure step. This image-wise transition is obtained by exposure to infrared laser irradiation at a wavelength of 1064 nm at high power which induces local ablation and formation of substoichiometric zirconia. U.S. Pat. No. 5,893,328, U.S. Pat. No. 5,836,248 and U.S. Pat. No. 5,836,249 disclose a printing material comprising a composite of zirconia alloy and α-alumina which can be imaged using similar exposure means to cause localized “melting” of the alloy in the exposed areas and thereby creating hydrophobic/oleophilic surfaces. A similar printing material containing an alloy of zirconium oxide and Yttrium oxide is described in U.S. Pat. No. 5,870,956. The high laser power output required in these prior art methods implies the use of expensive exposure devices.

EP 1,002,643 discloses a printing plate comprising an anodized titanium metal sheet which becomes hydrophilic or ink-repellent upon image-wise exposure to actinic light. Said printing plate can be regenerated after printing by first cleaning the plate and subsequently subjecting the plate to a heat-treatment step whereby the plate surface becomes evenly oleophilic or ink-accepting.

U.S. Pat. No. 6,240,091 discloses a method of producing a lithographic printing plate by image-wise irradiation of a printing plate precursor which comprises a support having a hydrophilic, metallic compound layer with photo-catalytic properties and light-heat convertible minute particles onto said layer, whereby the polarity of the metallic layer is converted and a hydrophobic area is obtained.

U.S. Pat. No. 6,455,222 discloses a lithographic printing plate precursor comprising fine hydrophilic light-heat convertible particles such as inorganic metal oxides including TiOₓ (x=1.0-2.0), SiOₓ (x=0.6-2.0) and AlOₓ (x=1.0-2.0) which are converted from a hydrophilic state into a hydrophobic state by the action of heat.

EP 903,223 and U.S. Pat. No. 6,391,522 disclose a printing plate precursor comprising a surface having a thin layer of for example TiO₂ which can be provided on said precursor with a vacuum deposition process wherein a partial oxygen pressure of 30% to 90% is used. The obtained titanium oxide layer is in a hydrophobic state and after exposure with actinic light through a film mask becomes hydrophilic at the exposed areas. Subsequent heating results in a hydrophilic/hydrophobic conversion.

U.S. Pat. No. 6,694,880 discloses a printing plate comprising a layer of titanium oxide which can be applied by vacuum-evaporation under an oxygen partial pressure ratio of 5 to 90% or by sputtering under an oxygen partial pressure ratio of 40%. The surface of the precursor becomes hydrophilic due to overall heating at a first temperature and by subsequent image-wise heating at a second temperature which is lower than the first temperature, hydrophobic printing areas are created.

A major problem associated with the prior art materials based on metal oxides is that these materials require exposure with high power laser light and/or the use of expensive exposure devices. Other plates based on metal oxides have to undergo a photo-reduction reaction prior to their use to induce a hydrophobic/hydrophilic conversion. This photo-reduction reaction can be initiated by for example a pre-heat treatment step and/or a flood UV-exposure step which have to be performed by the end-user. Such pre-treatment steps make plate making a cumbersome process.

### SUMMARY OF THE INVENTION

It is an object of the present invention to provide a non-ablative, negative-working, heat-sensitive lithographic printing plate precursor which requires no processing step and which can be directly exposed to heat and/or infrared light by means of a laser with low power output and without the need for a flood UV-exposure pre-treatment.

This object is realized by claim 1; i.e. a non-ablative, negative-working, heat-sensitive lithographic printing plate precursor obtainable by the method comprising the step of providing a titanium oxide layer on a support by reactive physical vacuum deposition of titanium, characterised in that said vacuum deposition is carried out under a partial oxygen pressure of 10% or more and less than 25%. Within this range of partial oxygen pressure, it was found that the obtained titanium oxide is sufficiently hydrophilic for the purpose of lithographic printing.

Other features, elements, steps, characteristics and advantages of the present invention will become more apparent from the following detailed description of preferred embodiments of the present invention.

### DETAILED DESCRIPTION OF THE INVENTION

According to the present invention, a layer of titanium oxide is provided on a lithographic support by reactive physical vacuum deposition of titanium under a reduced oxygen pressure of 10% or more and less than 25%. Physical vacuum deposition is a process where material vaporized from a solid or liquid source is transported as a vapor through a vacuum or low-pressure gas or plasma and which condenses and forms a layer when it contacts a substrate. Physical vacuum deposition can be performed by for example physical vacuum evaporation or sputtering deposition. The physical vacuum evaporation process is a process wherein the material to be coated is heated until it evaporates and which then reaches the substrate to be coated preferably without collision with gas molecules in the space between the source and substrate. Typically, physical vacuum evaporation takes place in a gas pressure range of 13,33.10⁻⁴ Pa-13,33.10⁻⁸ Pa (10⁻⁵ to 10⁻⁹ Torr), depending on the level of contamination that can be tolerated in the deposited layer. Inert gases such as for example argon are frequently used. Typical vaporization sources are resistively heated stranded wires or crucible steel, or high-energy electron beams that are focused and scanned over the surface of the source material. The vaporized material may be an element, alloy or compound. The physical vacuum evaporation process can be used to deposit layers of compound materials by the reaction of depositing material with the gas in the deposition environment and is called reactive physical vacuum evaporation. In the reactive physical vacuum evaporation process, a reactive gas such as oxygen or nitrogen can be mixed with the inert gas such as argon and by varying the relative pressures of the inert and reactive gases, the composition of the layer can be determined. Sputtering deposition is a non-thermal vaporization process wherein surface atoms of a solid target material are physically ejected into the gas phase by bombardment of the target material with energetic ions. These energetic ions are usually supplied by a plasma that is induced in the sputtering equipment by introducing a small amount of inert gas such as argon or nitrogen and applying a high voltage between electrodes. Sputter deposition can be performed in a vacuum or low-pressure gas typically below 13,33.10⁻² Pa-13,33.10⁻⁷ Pa (10⁻³-10⁻⁸ Torr) whereby the sputtered particles do not suffer gas-phase collisions in the space between the target and the substrate. It can also be carried out in a higher gas pressure whereby energetic particles that are sputtered or reflected from the sputtering target encounter gas-phase collisions before they reach the substrate. A variety of techniques can be used to modify the plasma properties—such as the ion density—to achieve the optimal sputtering conditions, including usage of RF (radio frequency) alternating current, utilization of magnetic fields, and application of a bias voltage to the target. Sputtering sources are usually magnetrons that utilize strong electric and magnetic fields. Magnetron sputtering units are typically provided with an RF (radio frequency) source. The sputter gas is inert, typically argon. Reactive sputtering refers to a technique where the deposited film is formed by chemical reaction between the target material and a gas which is introduced into the vacuum chamber. Oxide and nitride layers are often fabricated using reactive sputtering. The composition of the layer can be controlled by varying the relative pressures of the inert and reactive gases. In the present invention, reactive sputtering deposition is the preferred technique.

In a preferred embodiment a metal titanium target having preferably a 99.50% wt to 99.9% wt purity is provided in a vacuum deposition apparatus—such as for example a magnetron sputtering unit or a vacuum evaporating apparatus comprising an evaporating heat source—under a degree of vacuum of 13,33.10⁻⁴ Pa to 13,33.10⁻⁷ Pa (10⁻⁵ to 10⁻⁸ Torr) at a total gas pressure of 13,33 Pa-13,33.10⁻⁴ Pa (10⁻¹ to 10⁻⁵ Torr) and an oxygen partial pressure ratio of 10% or more and less than 25%. The reaction time preferably ranges from 1 to 60 minutes and the thickness of the deposited titanium metal oxide layer preferably varies from 0.01 μm to 10 μm, more preferably from 0.05 μm to 1.0 μm, most preferably between 0.10 μm and 0.30 μm.

It was surprisingly found that a titanium oxide layer provided on a lithographic support by the reactive physical vacuum deposition of titanium utilising a gas mixture having a partial oxygen pressure of 10% or more and less than 25%, more preferably ranging between 10% and 20% and most preferably a partial oxygen pressure ranging between of 15% or more and less than 25%, has hydrophilic properties, meaning that the titanium oxide layer is sufficiently hydrophilic for the purpose of lithographic printing. Deposition of titanium oxide utilising a partial oxygen pressure outside the specified range, does not result in a titanium oxide layer having such hydrophilic properties. By exposing the obtained support with the hydropilic titanium oxide surface to heat and/or infrared light, a convertion from a hydrophilic state into a hydrophobic state is obtained. Furthermore, after printing, the printing plate can be re-used by overall exposure to UV light whereby the hydrophobic areas are converted back to hydrophilic areas. Areas having hydrophilic properties or being in a hydrophilic state means areas that have a higher affinity for an aqueous solution than for an oleophilic ink; areas having hydrophobic properties or being in a hydrophobic state means that these areas have a higher affinity for an oleophilic ink than for an aqueous solution.

The lithographic support onto which the thin layer of titanium oxide is applied may be a metal sheet including for example aluminum, stainless steel, nickel, and copper. Also suitable as a support is a flexible plastic support such as polyester or cellulose ester, waterproof paper, polyethylene-laminated paper, or polyethylene-impregnated paper. The support can also be a laminate comprising an aluminum foil and a plastic layer, e.g. polyester film.

When a metal sheet is used as a support, the surface of the metal sheet may have been roughened by any of the known methods. The surface roughening may be conducted by mechanical means, electrochemical means and chemical etching means, or by combinations of these methods.

A particularly preferred lithographic support is an electrochemically grained and anodized aluminum support. The grained and anodized aluminum support is preferably grained by electrochemical graining, and anodized by means of anodizing techniques employing phosphoric acid or a sulphuric acid/phosphoric acid mixture. Methods of both graining and anodization of aluminum are very well known in the art.

By anodizing the aluminium support, its abrasion resistance and hydrophilic nature are improved. The microstructure as well as the thickness of the Al₂O₃ layer are determined by the anodizing step, the anodic weight (g/m² Al₂O₃ formed on the aluminium surface) typically varies between 1 and 8 g/m².

One or more layer(s) which comprise one or more compounds capable of absorbing light and converting the absorbed energy into heat may optionally be coated onto the support before or after the application of the titanium oxide layer. The compound capable of absorbing light and converting it into heat is preferably an infrared absorbing agent. Preferred IR absorbing compounds are dyes such as cyanine, merocyanine, indoaniline, oxonol, pyrilium and squarilium dyes or pigments such as carbon black. Examples of suitable infrared absorbers are described in e.g. EP 823 327, EP 978 376, EP 1 029 667, EP 1 053 868, EP 1 093 934; WO 97/39894 and WO 00/29214. Infrared absorbing dyes which become intensively colored after exposure by infrared irradiation or heating and thereby form a visible image, are particularly preferred. These dyes of high interest are extensively described in EP 1 614 541 and PCT 2006/063327. Other preferred IR compounds are the following cyanine dyes IR-1 and IR-2:

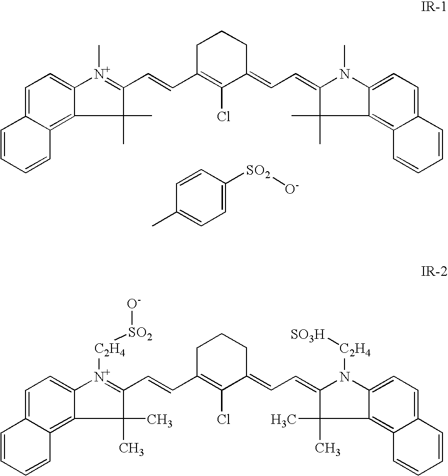

The coating may in addition to the layer comprising the infrared absorbing agent also contain one or more additional layer(s) such as i.e. a protective layer or an adhesion-improving layer between the support and the titanium oxide layer, and/or between the support and the layer comprising the infrared absorbing agent, and/or between the titanium oxide layer and the layer comprising the infrared absorbing agent.

Optionally, the layer comprising a compound capable of absorbing light or an optional other layer may further contain additional ingredients. For example binders, surfactants such as perfluoro surfactants, fillers or colorants may be present.

The heat-sensitive printing plate precursor thus obtained can be image-wise exposed directly with heat or indirectly with infrared light, preferably near infrared light. The infrared light is preferably converted into heat by an infrared light absorbing compound as discussed above.

The printing plate precursor can be exposed to infrared light by means of e.g. LEDs or an infrared laser. Preferably, the light used for the exposure is a laser emitting near infrared light having a wavelength in the range from about 700 nm to about 1500 nm, e.g. a semiconductor laser diode, a Nd:YAG or a Nd:YLF laser.

The exposure step may optionally be followed by a rinsing step and/or a gumming step. The gumming step involves post-treatment of the heat-sensitive printing plate with a gum solution. A gum solution is typically an aqueous liquid which comprises one or more surface protective compounds that are capable of protecting the lithographic image of a heat-sensitive material or printing plate against contamination or damaging. Suitable examples of such compounds are film-forming hydrophilic polymers or surfactants.

The heat-sensitive printing plate is then ready for printing without an additional development step. The exposed plate can be mounted on a conventional, so-called wet offset printing press in which ink and an aqueous dampening liquid are supplied to the material. The non-image areas hold the dampening water and the image areas withhold the ink. A plurality of printed copies are produced by transferring the ink to paper.

Another suitable printing method uses so-called single-fluid ink without a dampening liquid. Suitable single-fluid inks have been described in U.S. Pat. No. 4,045,232; U.S. Pat. No. 4,981,517 and U.S. Pat. No. 6,140,392. In a most preferred embodiment, the single-fluid ink comprises an ink phase, also called the hydrophobic or oleophilic phase, and a polyol phase as described in WO 00/32705.

Alternatively, the printing plate is first mounted on the printing cylinder of the printing press and then image-wise exposed directly on the press by means of an integrated image-recording device. Subsequent to exposure, the plate is ready for printing.

The printing plate can be regenerated after printing. After printing, the printing plate can be subjected to a flood exposure with UV light whereby hydrophobic areas are converted into a hydrophilic state and recover sensitivity to infrared light and/or heat irradiation. Optionally, before the flood exposure step, a cleaning step may be performed to remove the adherent ink. Suitable solvents that can be used for cleaning include solvents such as aromatic hydrocarbons commercially available as printing ink solvents, e.g. kerosine, benzene, toluene, xylene, acetone, methyl ethyl ketone, or mixtures thereof.

The regenerated printing plate precursor thus obtained can be used for a next printing operation involving image-wise exposure and printing.

### Examples

### Example 1

1. Preparation of the Aluminum Substrate.

A 0.3 mm thick aluminium foil was degreased by spraying with an aqueous solution containing 34 g/l NaOH at 70° C. for 6 seconds and rinsed with demineralised water for 3.6 seconds. The foil was then electrochemically grained during 8 seconds using an alternating current in an aqueous solution containing 15 g/l HCl, 15 g/l SO4²⁻ ions and 5 g/l Al³⁺ ions at a temperature of 37° C. and a current density of about 100 A/dm² (charge density of about 800 C/dm²). Afterwards, the aluminium foil was desmutted by etching with an aqueous solution containing 145 g/l of sulphuric acid at 80° C. for 5 seconds and rinsed with demineralised water for 4 seconds. The foil was subsequently subjected to anodic oxidation during 10 seconds in an aqueous solution containing 145 g/l of sulphuric acid at a temperature of 57° C. and a current density of 33 A/dm² (charge density of 330 C/dm²), then washed with demineralised water for 7 seconds and dried at 120° C. for 7 seconds. The support thus obtained is characterised by a surface roughness Ra of 0.35-0.4 μm (measured with interferometer NT1100, Optical Profiler available from Wyko) and has an anodic weight of 4.0 g/m².

2. Sputtering of the Titanium Oxide Layer.

The Aluminum support was introduced in a magnetron sputtering unit commercially available form Atom Tech Ltd. system and a target of 99.99% titanium was used. The pressure in the deposition chamber was reduced to 1.3 10⁻⁴ Pa (10⁻⁶ Torr). Sputtering deposition was carried out in a gas flow mixture of argon/oxygen according to Table 1 at a total pressure of 1.33 Pa (10⁻² Torr) and at a constant current of 5 A. The sputtering time was adapted for each argon/oxygen ratio in order to yield a sputtered layer thickness of 200 nm. The thickness calibration of the sputtered layer was done using a flat glass substrate which was introduced under the same sputtering conditions as used for the roughened aluminum support. The sputtered deposited layer is in essence amorphous.

TABLE 1
Sputtering conditions.

| | | | Sputtering |
|---|---|---|---|
| Printing plate | | | time |
| precursor | Ar flow* % | O₂ flow** % | minutes |
| PPP-01, comparative | 30 | 70 | 45 |
| PPP-02, comparative | 75 | 25 | 60 |
| PPP-03, inventive | 78 | 22 | 60 |
| PPP-04, inventive | 80 | 20 | 20 |
| PPP-05, inventive | 81 | 19 | 15 |
| PPP-06, inventive | 82 | 18 | 10 |
| PPP-07, inventive | 85 | 15 | 5 |
| PPP-08, inventive | 90 | 10 | 5 |
| PPP-09, comparative | 95 | 5 | 5 |
| PPP-10, comparative | 100 | 0 | 5 |

*argon partial pressure;
**oxygen partial pressure.

3. Exposure and Printing.

The printing plate precursors 1-10 were exposed using a 830 nm diode laser at three different power densities: 250 mJ/cm², 536 mJ/cm² and 822 mJ/cm².

Printing was done on a Heidelberg GTO46 press available from Heidelberger Druckmaschinen AG, Heidelberg, Germany, using 5% Agfa Prima FS101 as a fountain solution commercially available from Agfa Gevaert NV, and K+E Novavit 800 Skinnex ink commercially available from BASF Drucksysteme GmbH. 250 prints were made on 80 g offset paper. The print results are given in Table 2.

TABLE 2
print results.

| | | Image |
|---|---|---|
| | Sensitivity* | density on |
| Printing plates | mJ/cm² | print |
| PP-01, comparative | No image | — |
| PP-02, comparative | No image | — |
| PP-03, inventive | 536 | Low |
| PP-04, inventive | 536 | Medium |
| PP-05, inventive | 536 | High |
| PP-06, inventive | 536 | High |
| PP-07, inventive | 536 | High |
| PP-08, inventive | 536 | Low |
| PP-09, comparative | No image | — |
| PP-10, comparative | No image | — |

*Lowest IR-laser setting were a printed image is visible.

The printing plates 3 to 8 which were prepared using a partial oxygen pressure of 22% to 10% show an image after exposure to infrared light. The exposed areas are converted from a hydrophylic state into a hydrophobic state.

### Example 2

After the print job, the ink of PP-07 was removed using toluene and the entire sample was irradiated for 24 hours with a mercury lamp emitting at 254 nm at a power density of 0.5 mW/cm².

The UV-treated sample was then exposed again with the IR-laser as described in Example 1. The laser exposure areas were chosen so, that they only coincided for 50% with the previous laser exposed areas.

Subsequently a print job was started under the same conditions as described in Example 1.

The prints obtained had the same quality as the prints obtained in Example 1 and the previous image was erased. This example shows that flood exposure of the printing plate with UV-light results in a precursor which can be re-used in a next cycle of imaging and printing.

1-10. (canceled)

11. A lithographic printing plate precursor obtainable by method comprising providing a titanium oxide layer on a support by reactive physical vacuum deposition of titanium, wherein the vacuum deposition is carried out under a partial oxygen pressure of 10% or more and less than 25%.

12. The printing plate precursor according to claim 11, wherein the reactive physical vacuum deposition is a reactive sputter deposition process.

13. The printing plate precursor according to claim 11, wherein the partial oxygen pressure is more than 15%.

14. The printing plate precursor according to claim 11, wherein the partial oxygen pressure ranges between 10% and 20%.

15. The printing plate precursor according to claim 11, wherein the titanium oxide layer has a thickness ranging between and 0.10 μm to 0.30 μm.

16. The printing plate precursor according to claim 11, wherein a layer comprising one or more infrared absorbing agent(s) is provided before or after the application of the titanium oxide layer.

17. The printing plate precursor according to claim 16, wherein at least one of the infrared absorbing agents is a compound which provides a visible image after image-wise exposure to heat and/or infrared light.

18. The printing plate precursor according to claim 11, wherein the titanium oxide layer is hydrophilic.

19. A method for making a printing plate comprising the steps of:
(i) providing a printing plate precursor according to claim 11; and
(ii) exposing said precursor with heat and/or infrared light whereby the titanium oxide layer is converted from a hydrophilic state into a hydrophobic state.

20. A lithographic printing method comprising the steps of
(i) providing a lithographic printing plate precursor according to claim 11;
(ii) providing a printing plate by exposing the precursor with heat and/or infrared light whereby the titanium oxide layer is converted from a hydrophilic state into a hydrophobic state;
(iii) producing a plurality of printed copies by supplying ink to the printing plate and transferring the ink to paper;
(iv) optionally cleaning the printing plate by removing the ink from the plate;
(v) erasing the lithographic image by flood-exposing the printing plate to UV light thereby converting hydrophobic areas of the surface to a hydrophilic state; and
(vi) re-using the precursor thus obtained in a next cycle comprising steps (i) to (iv).
This listing of claims replaces all prior versions, and listings, of claims in the application.
